(19) United States
(12) Patent Application Publication
(10) Pub. No.: US 2019/0371829 A1
(43) Pub. Date: Dec. 5, 2019

(54) METHOD FOR MANUFACTURING ACTIVE MATRIX SUBSTRATE AND METHOD FOR MANUFACTURING ORGANIC EL DISPLAY

(71) Applicant: SHARP KABUSHIKI KABUSHIKI KAISHA, Sakai City, Osaka (JP)

(72) Inventors: Takao SAITOH, Sakai City (JP); Yohsuke KANZAKI, Sakai City (JP); Masahiko MIWA, Sakai City (JP); Masaki YAMANAKA, Sakai City (JP); Seiji KANEKO, Sakai City (JP)

(73) Assignee: Sharp Kabushiki Kaisha, Sakai City, Osaka (JP)

(21) Appl. No.: 16/064,536

(22) PCT Filed: Feb. 28, 2017
(86) PCT No.: PCT/JP2017/007891

§ 371 Date: Sep. 7, 2018

(51) Int. Cl. H01L 27/12; H01L 27/32; H01L 51/56; H01L 51/52; H01L 21/8234

(52) U.S. Cl. CPC H01L 27/1262; H01L 27/1248; H01L 27/3244; H01L 2021/775; H01L 51/524; H01L 21/823437; H01L 51/56

(57) ABSTRACT

In formation of a gate electrode, a metal film forming a gate electrode of TFT is formed on a gate insulating film covering a semiconductor layer having an island shape, the gate electrode is formed on the metal film by dry etching, and the exposed gate electrode is subjected to a plasma treatment using oxygen or nitrogen. This prevents formation of needle-shaped or granular crystal while a reduction in production efficiency is suppressed.

### TECHNICAL FIELD

The disclosure relates to a method for manufacturing an active matrix substrate and a method for manufacturing an organic EL display device.

### BACKGROUND ART

In a Thin Film Transistor (TFT) using a low-temperature polysilicon, a so-called top gate structure, in which a gate electrode is disposed on a layer above a semiconductor layer, is adapted.

The gate electrode is formed by patterning, and impurity ions are then injected into the semiconductor layer of the TFT, to form such a TFT. Subsequently, the semiconductor layer is annealed for activation of the semiconductor layer. At that time, a surface of the gate electrode is oxidized by heat since the gate electrode is exposed.

In PTL 1, the semiconductor layer is annealed in an environment where oxygen in the atmosphere is removed as much as possible during annealing for activation. According to PTL 1, oxidation of the surface of the gate electrode can be suppressed.

### CITATION LIST

### Patent Literature

PTL 1: JP 2015-64592 A

### SUMMARY

### Technical Problem

The gate electrode is also heated by annealing the semiconductor layer. Subsequently, the temperature in a furnace in which annealing is carried out is abruptly returned to the atmospheric temperature. In this case, the oxidized surface of the gate electrode is abruptly cooled. As a result, a needle-shaped or granular crystal is formed on the surface of the gate electrode. Due to the needle-shaped or granular crystal formed on the surface, the coverage of an insulating layer that covers the gate electrode may be deteriorated and the resistance value of the gate electrode may increase. This causes a decrease in yield.

In a method of PTL 1, the temperature of the substrate, which is heated under a reduced pressure environment, needs to be sufficiently reduced before the pressure is brought back to the atmospheric pressure. Therefore, the time required for annealing of the semiconductor layer is longer.

The gate electrode needs to be patterned to a tapered shape, to improve the coverage of the insulating layer that covers the gate electrode. When the gate electrode is patterned to a tapered shape, dry etching, rather than wet etching, is used.

Chlorine or fluorine used in this dry etching may be deposited to the surface of the gate electrode after patterning. When the gate electrode is heated while the chlorine or fluorine is deposited on, oxidation may proceed. As a result, a needle-shaped or granular crystal is likely to be formed on the surface.

In view of the above-described problems of the related art, an object of the disclosure is to prevent formation of a needle-shaped or granular crystal on a surface of a gate electrode due to heat generated during activation of a semiconductor layer in a TFT with a top gate structure while a reduction in productivity is suppressed.

### Solution to Problem

In order to solve the above-described problems, a method for manufacturing an active matrix substrate according to one aspect of the disclosure is a method for manufacturing an active matrix substrate having a TFT with a top gate structure on a substrate including: (i) forming a gate insulating film on the substrate, the gate insulating film covering a semiconductor layer formed in an island shape on the substrate; (ii) forming a metal film on the gate insulating film followed by dry etching to form a gate electrode of the TFT, the metal film forming the gate electrode; and (iii) subjecting the gate electrode to a plasma treatment using oxygen or nitrogen after step (ii), the gate electrode being exposed.

### Advantageous Effects of Disclosure

One aspect of the disclosure has an effect of preventing formation of a needle-shaped or granular crystal on a surface of a gate electrode due to heat generated during activation of a semiconductor layer in a TFT with a top gate structure while a reduction in productivity is suppressed.

### BRIEF DESCRIPTION OF DRAWINGS

FIG. 1 is a cross-sectional view illustrating a configuration of an organic EL display device according to a first embodiment of the disclosure.

FIG. 2 is a plan view illustrating a configuration of a TFT substrate according to the first embodiment of the disclosure.

FIGS. 3A to 3F are cross-sectional views illustrating a process for manufacturing the TFT substrate according to the first embodiment of the disclosure.

FIG. 4 is a cross-sectional view illustrating a configuration of a TFT substrate according to a second embodiment of the disclosure.

FIG. 5 is a chart illustrating a process for manufacturing the TFT substrate according to the second embodiment of the disclosure.

FIGS. 6A and 6B are views illustrating a state of a gate electrode when the substrate having the gate electrode is removed from a furnace immediately after annealing.

FIGS. 7A and 7B are views illustrating a state of the gate electrode removed from a furnace, after the substrate having the gate electrode was annealed and allowing the temperature in the furnace to decrease down to 50° C.

FIGS. 8A and 8B are views illustrating a state of a gate electrode, when the substrate having the gate electrode is removed from a furnace after annealing in a low-oxygen environment.

### DESCRIPTION OF EMBODIMENTS

### First Embodiment

### Schematic Configuration of Organic EL Display Device 1

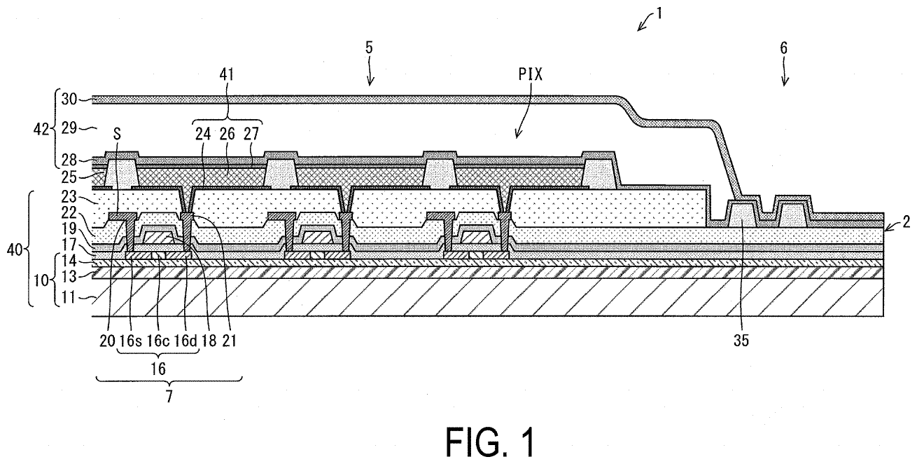

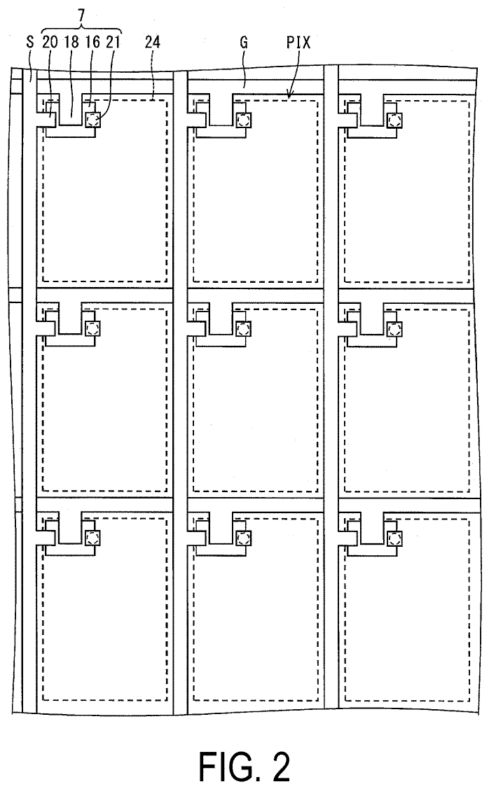

A schematic configuration of an organic EL display device 1 will be described by using FIGS. 1 and 2, as one example of a display device using a Thin Film Transistor (TFT) 7 according to an embodiment of the disclosure.

FIG. 1 is a cross-sectional view illustrating the configuration of the organic EL display device 1 according to a first embodiment of the disclosure. As illustrated in FIG. 1, the organic EL display device 1 includes an organic EL substrate 2 sealed with a thin film (Thin Film Encapsulation, TFE) and a drive circuit (not illustrated). The organic EL display device 1 may further include a touch panel.

The organic EL display device 1 has a display region 5 that has a pixel PIX disposed in a matrix and displays an image and a frame region 6 that is a peripheral region surrounding the display region 5 and does not have the pixel PIX.

The organic EL substrate 2 has a structure in which an organic EL element 41 and a sealing layer 42 are provided on a Thin Film Transistor (TFT) substrate 40 in this order from the side of the TFT substrate (active matrix substrate) 40.

The organic EL substrate 2 includes a support 11. The support 11 includes a transparent insulating material such as a plastic film and a glass substrate. On the entire surface of the support 11, a plastic film 13 including a resin such as a polyimide (PI), a moisture-proof layer 14, and the like are provided in this order from the side of the support 11.

On the moisture-proof layer 14, an island-shaped semiconductor layer 16, a gate insulating film 17 that covers the semiconductor layer 16 and the moisture-proof layer 14, a gate electrode 18 that is provided on the gate insulating film 17 and overlaps the semiconductor layer 16, a first interlayer film 19 that covers the gate electrode 18 and the gate insulating film 17, a second interlayer film 22 that covers the first interlayer film 19, and an interlayer insulating film 23 that covers the second interlayer film 22 are provided.

The semiconductor layer 16 has a channel region 16c, a source region 16s, and a drain region 16d. The gate electrode 18 is formed to cover the channel region 16c and a part of the source region 16s and a part of the drain region 16d.

A source electrode 20 is connected to the source region 16s and a drain electrode 21 is connected to the drain region 16d, via contact holes provided in the gate insulating film 17, the first interlayer film 19, and the second interlayer film 22.

A TFT 7 includes the semiconductor layer 16, the gate electrode 18, the source electrode 20, and the drain electrode 21. The TFT 7 is a switching element that is formed in each pixel PIX and controls drive of each of the pixels PIXs. The TFT 7 has a so-called top gate structure (staggered type) in which the gate electrode 18 is formed as an upper layer on the semiconductor layer 16. In this embodiment, the semiconductor layer 16 includes a low-temperature polysilicon (LTPS).

The gate electrode 18 can include molybdenum, a molybdenum alloy containing molybdenum such as molybdenum tungsten (MoW), tungsten, a tungsten alloy containing tungsten such as tungsten tantalum, or the like.

In particular, it is preferable that the gate electrode 18 include molybdenum or a molybdenum alloy, rather than from tungsten or a tungsten alloy. This is because the resistance value is lower. However, when the gate electrode 18 includes molybdenum or a molybdenum alloy, a surface thereof is more easily oxidized by heat than that including tungsten or a tungsten alloy.

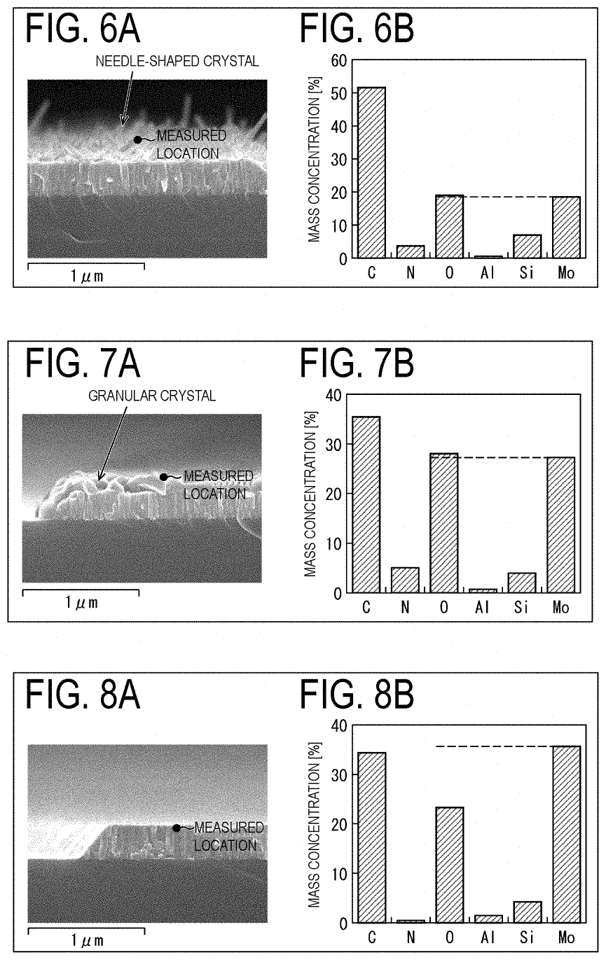

The surface is oxidized by heat, and the temperature is abruptly brought back to the atmospheric temperature, to cool the surface. In this case, a needle-shaped crystal (see FIG. 6A) or a granular crystal (see FIG. 7A) is formed on the surface of the gate electrode. When the needle-shaped or granular crystal is formed on the surface, the coverage of the first interlayer film 19 covering the gate electrode 18 may be deteriorated. This causes a decrease in yield. Due to the formation of needle-shaped or granular crystal, the resistance value of the gate electrode may increase. This also causes a decrease in yield. Therefore, when the gate electrode 18 includes molybdenum or a molybdenum alloy, it is particularly preferable that a procedure of preventing oxidation of the surface be carried out.

The support 11, the plastic film 13, and the moisture-proof layer 14, which are layers below the TFT 7, may be simply referred to as a substrate 10. That is, it may be also expressed that the TFT 7 is formed on the substrate 10.

The first interlayer film 19 and the second interlayer film 22 are an inorganic insulating film including silicon nitride or silicon oxide. The second interlayer film 22 covers a leading wiring line (not illustrated), and the like. The interlayer insulating film 23 is an organic insulating film including a photosensitive resin such as an acrylic or a polyimide. The interlayer insulating film 23 covers the TFT 7 and a wiring line (not illustrated). Thus, unevenness on the TFT 7 and the wiring line (not illustrated) is leveled.

In this embodiment, the interlayer insulating film 23 is provided on the display region 5, but is not provided on the frame region 6. However, the interlayer insulating film 23 may be provided not only on the display region 5 but also on the frame region 6.

FIG. 2 is a plan view illustrating a configuration of the TFT substrate according to the first embodiment of the disclosure. As illustrated in FIG. 2, the gate electrode 18 of the TFT 7 is connected to a gate wiring line G and the source electrode 20 is connected to a source wiring line S. As seen from a direction perpendicular to a substrate surface of the organic EL substrate 2, a plurality of the gate wiring lines G arranged in parallel and a plurality of the source wiring lines S arranged in parallel intersect orthogonally. A region defined by the gate wiring line G and the source wiring line S is the pixel PIX.

The TFT 7 is provided in the pixel PIX and in the vicinity of an intersection between the gate wiring line G and the source wiring line S. A lower electrode 24 is formed in an island shape in the pixel PIX.

As illustrated in FIG. 1, the lower electrode 24 is formed on the interlayer insulating film 23. The lower electrode 24 is connected to the drain electrode 21 via a contact hole provided in the interlayer insulating film 23.

An organic EL element 41 includes the lower electrode 24, an organic EL layer 26, and an upper electrode 27. The organic EL element 41 is a light-emitting element capable of emitting light at high luminance by low-voltage direct current drive. The lower electrode 24, the organic EL layer 26, and the upper electrode 27 are layered in this order from the side of the TFT substrate 40. In this embodiment, layers between the lower electrode 24 and the upper electrode 27 are collectively referred to as the organic EL layer 26.

On the upper electrode 27, an optical adjustment layer that performs optical adjustment and an electrode protection layer that protects an electrode may be formed. In this embodiment, layers formed in each of the pixels PIXs including the organic EL layer 26, electrode layers (the lower electrode 24 and the upper electrode 27), and the optical adjustment layer and the electrode protection layer that are formed as necessary and are not illustrated in the drawings are collectively referred to as the organic EL element 41.

In the lower electrode 24, a hole is injected into (supplied to) the organic EL layer 26. In the upper electrode 27, an electrode is injected into the organic EL layer 26.

The hole and electron injected into the organic EL layer 26 are recombined in the organic EL layer 26, to form an exciton. When the formed exciton is decayed from an excited state to a ground state, light such as red light, green light, or blue light is emitted, and the emitted light exits from the organic EL element 41 to the outside.

An end of the lower electrode 24 having an island shape is covered with an edge cover 25. The edge cover 25 is formed on the interlayer insulating film 23 to cover the end of the lower electrode 24. The edge cover 25 is an organic insulating layer including a photosensitive resin such as an acrylic or a polyimide.

The edge cover 25 is disposed between the pixels PIXs adjacent to each other. The edge cover 25 prevents a short circuit of the upper electrode 27 that may be caused by concentration of the electrodes or a decrease in thickness of the organic EL layer 26 at the end of the lower electrode 24. Further, the concentration of electric field at the end of the lower electrode 24 is prevented by the presence of the edge cover 25. Thus, the deterioration of the organic EL layer 26 is prevented.

The organic EL layer 26 is provided at a region surrounded by the edge cover 25. In other words, the edge cover 25 surrounds an edge of the organic EL layer 26 and a side wall of the edge cover 25 is in contact with a side wall of the organic EL layer 26. When the organic EL layer 26 is formed by an inkjet method, the edge cover 25 functions as a bank that blocks a liquid material that forms the organic EL layer 26. The edge cover 25 has a tapered cross section.

The organic EL layer 26 is provided at the region surrounded by the edge cover 25 in the pixel PIX. The organic EL layer 26 can be formed by a vapor deposition method, an inkjet method, or the like.

For example, the organic EL layer 26 has a structure in which a hole injecting layer, a hole transport layer, a light-emitting layer, an electron transport layer, an electron injecting layer, and the like are layered in this order from the side of the lower electrode 24. One layer may have a plurality of functions. For example, instead of the hole injecting layer and the hole transport layer, a hole injection-cum-transport layer having functions of both the hole injecting layer and the hole transport layer may be provided. Instead of the electron injecting layer and the electron transport layer, an electron injection-cum-transport layer having functions of both the electron injecting layer and the electron transport layer may be provided. Between the layers, a carrier blocking layer may be appropriately provided.

The upper electrode 27 is formed in an island shape in each of the pixels PIXs by patterning. The upper electrodes 27 formed in the pixels PIXs are connected to each other through an auxiliary wiring line (not illustrated) or the like. The upper electrode 27 may not be formed in an island shape in each of the pixels and may be formed at the entire surface of the display region 5.

In this embodiment, the lower electrode 24 is described as an anode (pattern electrode or pixel electrode) and the upper electrode 27 is described as a cathode (common electrode). However, the lower electrode 24 may be a cathode and the upper electrode 27 may be an anode. In this case, the order of the layers constituting the organic EL layer 26 is inverted.

When the organic EL display device 1 is a bottom emission type that emits light from a back side of the support 11, a reflective electrode includes a reflective electrode material as the upper electrode 27 and a transparent or semi-transparent electrode includes a transparent or semi-transparent translucent electrode material as the lower electrode 24.

In contrast, when the organic EL display device 1 is a top emission type that emits light from the side of the sealing layer 42, the electrode structure is the reverse of that of the bottom emission type. That is, when the organic EL display device 1 is the top emission type, a reflective electrode is formed as the lower electrode 24 and a transparent or semi-transparent electrode is formed as the upper electrode 27.

A frame bank 35 (bank) is formed on the second interlayer film 22 within the frame region 6 to surround the display region 5 in a frame shape.

The frame bank 35 controls wetting and spreading of a liquid organic insulating material that forms an organic layer (resin layer) 29 of the sealing layer 42 during applying to the entire surface of the display region 5. When the organic insulating material is cured, the organic layer 29 is formed. The frame bank 35 has a tapered cross section.

In this embodiment, the frame bank 35 doubly surrounds the display region 5. However, the frame bank 35 may only singly surround the display region 5 or triply or greater surround the display region 5.

The frame bank 35 is an organic insulating film including a photosensitive resin such as an acrylic or a polyimide. For the frame bank 35, the same material as that for the edge cover 25 can be used. The frame bank 35 may be formed by patterning using photolithography or the like in the same step as that for the edge cover 25.

The frame bank 35 may include a material different from that for the edge cover 25 by patterning in a step different from that for the edge cover 25.

The sealing layer 42 includes an inorganic layer 28, the organic layer 29, and an inorganic layer 30 that are layered in this order from the side of the TFT substrate 40. The sealing layer 42 covers the organic EL element 41, the edge cover 25, the interlayer insulating film 23, the second interlayer film 22, and the frame bank 35. Between the upper electrode 27 and the sealing layer 42, an organic layer (resin layer) or an inorganic layer such as the optical adjustment layer and the electrode protection layer, which are not illustrated, may be formed, as described above.

The organic EL layer 26 is sealed with the sealing layer 42 (thin film encapsulation, TFE). Thus, the sealing layer 42 prevents the deterioration of the organic EL element 41 due to moisture and oxygen permeated from the outside.

The inorganic layers 28 and 30 have a moisture-proof function that prevents permeation of moisture, and thus the deterioration of the organic EL element 41 due to moisture and oxygen is prevented.

The organic layer 29 may relax the stress of the inorganic layers 28 and 30 having a large film stress. Also, the organic layer 29 may level the surface of the organic EL element 41 by embedding a step, eliminate a pinhole, and suppress cracking during layering the inorganic layers, and film separation.

The aforementioned layered structure is one example. The sealing layer 42 is not limited to the aforementioned three-layer structure (the inorganic layer 28/the organic layer 29/the inorganic layer 30). The sealing layer 42 may have a structure in which an inorganic layer and an organic layer are layered in not less than four layers.

Examples of a material for the organic layer include organic insulating materials (resin materials) such as a polysiloxane, silicon oxide carbide (SiOC), an acrylate, a polyurea, parylene, a polyimide, and a polyamide.

Examples of a material for the inorganic layer include inorganic insulating materials such as silicon nitride, silicon oxide, silicon oxynitride, and Al₂O₃.

### Method for Manufacturing TFT Substrate 40

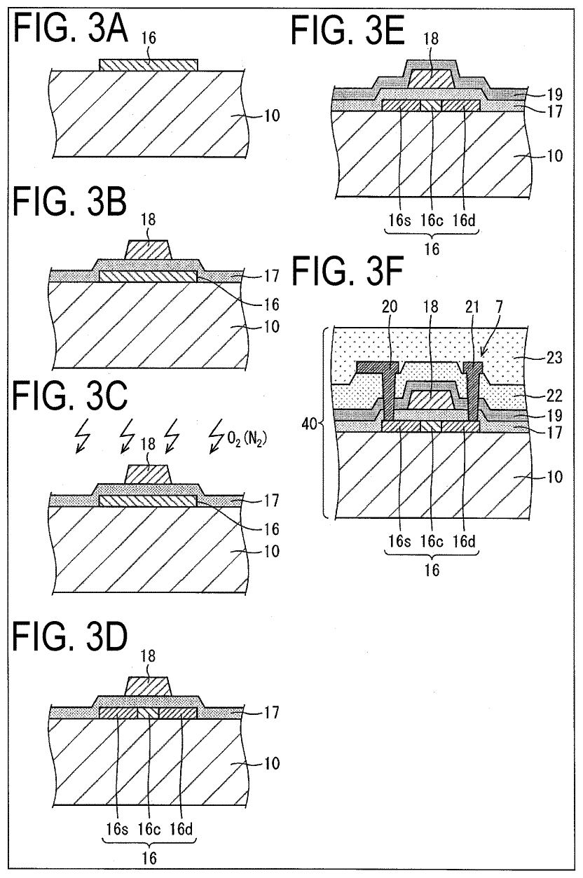

Next, one example of a method for manufacturing the TFT substrate 40 will be described by using FIGS. 1 and 3A to 3F.

FIGS. 3A to 3F are cross-sectional views illustrating a process for manufacturing the TFT substrate 40 according to the first embodiment of the disclosure. FIG. 3A is a view illustrating a state where the semiconductor layer 16 is formed on the substrate 10. FIG. 3B is a view illustrating a state where the gate electrode is formed. FIG. 3C is a view illustrating a state where a plasma treatment is carried out immediately after formation of the gate electrode. FIG. 3D is a view illustrating a state where the semiconductor layer 16 is activated. FIG. 3E is a view illustrating a state where the first interlayer film 19 is formed. FIG. 3F is a view illustrating a state where the interlayer insulating film 23 is formed.

When a polyimide (PI) or the like is applied to the support 11 as illustrated in FIG. 1, the plastic film 13 is formed on the support 11 (PI application step). On the plastic film 13, an inorganic insulating film including silicon nitride, silicon oxide, or the like is formed by Chemical Vapor Deposition (CVD) or the like. Thus, the moisture-proof layer 14 is formed on the plastic film 13 (moisture-proof layer forming step). As a result, the substrate 10 is manufactured.

As illustrated in FIG. 3A, the semiconductor layer 16 having an island shape is formed on the substrate 10.

In order to form the semiconductor layer 16 having an island shape, an amorphous silicon (a-Si) film is first formed on the substrate 10 by chemical vapor deposition (CVD) or the like, and then irradiated with a laser beam, resulting in crystallization. Thus, a polysilicon (p-Si) film is formed. A resist film is formed on the polysilicon film and patterned by photolithography or the like. The polysilicon film is etched by using the patterned resist film as a patterning mask. Thus, the semiconductor layer 16 having an island shape is formed at a pixel forming region on the substrate 10.

As illustrated in FIG. 3B, the gate insulating film 17 including silicon nitride or silicone oxide is then formed on the substrate 10 to cover the semiconductor layer 16 by CVD or the like (gate insulating film forming step). Through the gate insulating film 17, impurities are doped (injected) into the semiconductor layer 16.

Subsequently, a metal film including molybdenum or an alloy containing molybdenum is formed on the entire surface of the gate insulating film 17 by sputtering or the like. The formed metal film is then patterned by dry etching using chlorine or fluorine (gate electrode forming step). As a result, the gate electrode 18 is formed on the gate insulating film 17 to overlap the semiconductor layer 16 through the gate insulating film 17.

It is preferable that the gate electrode 18 have a tapered shape (a shape in which a side surface is inclined so that the area is decreased from the bottom surface toward the top surface) and the coverage of the first interlayer film 19 over the gate electrode 18 is improved, where the first interlayer film 19 is formed to cover the gate electrode 18 in a subsequent step. For this reason, it is preferable that the gate electrode 18 be patterned by dry etching rather than wet etching.

The angle between the bottom surface and the side surface of the gate electrode 18 is referred to a taper angle. Preferably, the gate electrode 18 is patterned to result in the taper angle of not greater than 50°. When the gate electrode 18 is patterned by dry etching, the gate electrode having a taper angle of not greater than 50° can be formed by patterning. Thus, the coverage of the first interlayer film 19 for the gate electrode 18 can be sufficiently ensured.

During patterning of the gate electrode, dry etching is carried out, for example, at from 1 to 3 Pa, a flow rate of O₂ of from 200 to 500 sccm, a flow rate of Cl₂ of from 200 to 500 sccm, and from 0.5 to 1 w/cm².

It is difficult to form the gate electrode 18 having a taper angle of not greater than 50° by wet-etching.

The gate wiring line G (see FIG. 2) may include the same material as that for the gate electrode 18 and in the same step as that for the gate electrode 18, or include a material different from that for the gate electrode 18 and in a step different from that for the gate electrode 18.

When the gate electrode 18 is patterned by dry etching, but not by wet etching, chlorine or fluorine used during dry etching remains on the substrate after dry etching. In particular, when chlorine or fluorine is attached to the surface of the gate electrode 18, the oxidation of surface of the gate electrode 18 may be promoted by heat applied to the semiconductor layer 16 for activation of the semiconductor layer 16 described below.

As illustrated in FIG. 3C, immediately after the gate electrode 18 is patterned by dry etching, the substrate in which the gate electrode 18 is exposed is subjected to a plasma treatment using oxygen (O₂) or nitrogen (N₂) (plasma treatment step).

For example, this plasma treatment is carried out at from 1 to 3 Pa, a flow rate of O₂ of 1000 sccm, and from 0.2 to 1 W/cm².

As described above, the gate electrode 18 is patterned, and the gate electrode 18 exposed is subjected to the plasma treatment using oxygen or nitrogen. Thus, chlorine or fluorine that is used in dry etching and is attached to the gate electrode 18 can be removed. Therefore, the oxidation of surface of the gate electrode 18 by heat applied to the substrate for activation of the semiconductor layer 16 described below can be prevented.

This plasma treatment can shorten the time required for annealing compared to the time required for annealing of the semiconductor layer in a reduced pressure environment described in PTL 1. Further, the oxidation of surface of the gate electrode 18 can be prevented.

Subsequently, impurity ions such as boron ions are injected into the semiconductor layer 16 by using the gate electrode 18 as a mask, as illustrated in FIG. 3D (ion injecting step). As a result, the source region 16s and the drain region 16d between which the channel region 16c is interposed are formed in the semiconductor layer 16. The gate electrode 18 is exposed because the impurity ions are injected into the semiconductor layer 16 by using the gate electrode 18 as a mask.

Herein, it is necessary that the semiconductor layer 16 be heated to activate the semiconductor layer 16. However, in this embodiment, the semiconductor layer 16 is not annealed at that time. That is, the substrate is not heated with the gate electrode 18 exposed. Thus, the oxidation of the gate electrode 18 can be prevented.

As illustrated in FIG. 3E, the first interlayer film 19 including silicon nitride or silicon oxide is formed on the gate insulating film 17 to cover the exposed gate electrode 18 by CVD or the like. During formation of the first interlayer film 19, the substrate is heated at from 300° C. to 430° C. (interlayer film forming step).

For example, the CVD process is carried out at from 0.2 to 1 W/cm², a flow rate of SiH₄ of from 200 to 1000 sccm, a flow rate of NH₃ of from 1000 to 3000 sccm, and a flow rate of N₂ of from 5000 to 10000 sccm.

Thus, the semiconductor layer 16 is annealed. As a result, a Si crystal defect, which is generated during injection of impurity ions into the semiconductor layer 16, is recrystallized and the semiconductor layer 16 is activated.

In this embodiment, after the dry etching for patterning of the gate electrode 18, the plasma treatment using oxygen or nitrogen is carried out. Therefore, chlorine or fluorine residue that is used in the dry etching is removed from the surface of the gate electrode 18. Accordingly, even when the gate electrode 18 is heated, the oxidation of surface of the gate electrode 18 is suppressed.

In the interlayer film forming step, the first interlayer film 19 is in the process of accumulation on the gate electrode 18 that is exposed before the interlayer film forming step. Therefore, even when the substrate is heated, the oxidation of surface of the gate electrode 18 can be suppressed by the accumulated first interlayer film 19.

In the interlayer film forming step, the semiconductor layer 16 is annealed while the first interlayer film 19 is formed.

When the substrate is heated at not less than 300° C., and preferably not less than 350° C., the semiconductor layer 16 can be sufficiently annealed, resulting in activation. When the substrate is heated at not greater than 430° C., the deterioration of the formed first interlayer film 19 can be prevented.

Further, the mass concentration of molybdenum or molybdenum alloy in the surface of the gate electrode 18 can be made higher than that of oxygen and carbon.

Accordingly, in the interlayer film forming step, the semiconductor layer 16 can be annealed in a short time, and the oxidation of surface of the gate electrode 18 can be prevented.

After the first interlayer film 19 is formed, the second interlayer film 22 including silicon nitride or silicon oxide is formed by CVD or the like, as illustrated in FIG. 3F. When the second interlayer film 22 is formed, the temperature applied to the substrate may be about 250° C.

Subsequently, a contact hole is formed in the gate insulating film 17, the first interlayer film 19, and the second interlayer film 22, to expose a part of the source region 16s and a part of the drain region 16d of the semiconductor layer 16.

The source electrode 20 and the drain electrode 21 are formed by patterning using a publicly known technique. At that time, the source electrode 20 and the drain electrode 21 are connected to a part of the exposed source region 16s and a part of the drain region 16d, respectively, via the contact holes. Thus, the TFT 7 is formed.

The source wiring line S (see FIG. 2) may include the same material as that for the source electrode 20 and the drain electrode 21 and in the same step as that for the source electrode 20 and the drain electrode 21, or include a material different from that for the source electrode 20 and the drain electrode 21 and in a step different from that for the source electrode 20 and the drain electrode 21.

Next, a photosensitive resin such as an acrylic or a polyimide is patterned on the second interlayer film 22 by applying, photolithography, and the like, to cover the TFT 7. Thus, the interlayer insulating film 23 is formed. Thus, the TFT substrate 40 is completed.

### Method for Manufacturing Organic EL Display Device

After the TFT substrate 40 is completed, a contact hole is formed in a part of the interlayer insulating film 23 to expose the drain electrode 21, as illustrated in FIG. 1. At each of the pixels PIXs, the lower electrode 24 is formed in an island shape as a reflective electrode.

A resist material forming the edge cover 25 is applied to the entire surface of the substrate, to form a resist film. The resist film is patterned by photolithography. As a result, the edge cover 25 is formed in a lattice pattern to cover the edge of the lower electrode 24 arranged in a matrix (edge cover forming step). Further, the frame bank 35 is also formed to surround the display region 5 in a frame shape.

Subsequently, the organic EL layer 26 is patterned at the region surround by the edge cover 25 by vapor deposition by color or the like. The upper electrode 27 is formed on the organic EL layer 26 at the entire surface of the display region 5 by deposition or the like.

Subsequently, the sealing layer 42 is formed. Specifically, the inorganic layer 28 including silicon nitride or silicon oxide is formed to cover the upper electrode 27, the edge cover 25, and the interlayer insulating film 23 by CVD or the like. The organic layer 29 is formed on the inorganic layer 28 at the entire surface of the display region 5 by an inkjet method or the like. The inorganic layer 30 including silicon nitride or silicon oxide is formed on the organic layer 29 and the inorganic layer 28 by CVD or the like. As a result, the sealing layer 42 is formed.

After then, a drive circuit and the like are connected, to complete the organic EL display device 1. Note that, after the sealing layer 42 is formed, the support 11 may be changed from a glass substrate to a film, to make the organic EL display device 1 flexible.

In this embodiment, a case where the TFT substrate 40 is used in the organic EL display device 1 is described. However, a display device is not limited to the organic EL display device 1, and another display device such as a liquid crystal display device may be formed by using the TFT substrate 40.

### Second Embodiment

A second embodiment of the disclosure will be described below. For easy description, components having the same functions as those of the components described in the first embodiment are appended with the same reference signs, and the description thereof is omitted.

In the first embodiment as described by using FIGS. 3A to 3F, the semiconductor layer 16 is annealed in the interlayer film forming step in the method for manufacturing the TFT substrate 40, but not after the ion injection step.

In this embodiment, the substrate is heated at from 300° C. to 430° C. in a furnace in which the oxygen concentration is reduced before the interlayer film forming step after the ion injection step (annealing step). Thus, the oxidation of surface of the gate electrode 18 can be prevented during annealing of the semiconductor layer 16. After the annealing, the temperature of the furnace is slowly reduced and thus needle-shaped and granular crystals are not formed on the surface of the gate electrode 18. Subsequently, the substrate is removed from the furnace.

The gate electrode 18 is formed by patterning by dry etching, and then subjected to a plasma treatment using oxygen or nitrogen. Thus, chlorine or fluorine residue that is used in the dry etching is removed from the surface of the gate electrode 18. Accordingly, even when the gate electrode 18 is heated, the oxidation of surface of the gate electrode 18 is suppressed.

In this case, the oxygen concentration can be reduced in a shorter time as compared with a case where chlorine or fluorine remains in the surface of the gate electrode 18, and the substrate can be heated at from 300° C. to 430° C.

After the annealing step, the interlayer film forming step is carried out. In this embodiment, the semiconductor layer 16 is annealed before the interlayer film forming step. Therefore, in the interlayer film forming step, the temperature applied to the substrate during formation of the first interlayer film 19 may be about 250° C.

### Third Embodiment

A third embodiment of the disclosure will be described below. For easy description, components having the same functions as those of the components described in the first embodiment are appended with the same reference signs, and the description thereof is omitted.

In the first embodiment as described by using FIGS. 3A to 3F, the semiconductor layer 16 is annealed in the interlayer film forming step in the method for manufacturing the TFT substrate 40, but not after the ion injection step.

In this embodiment, the substrate is heated in an atmospheric pressure environment at from 300° C. to 430° C. before the interlayer film forming step after the ion injection step (annealing step).

In this embodiment, the gate electrode 18 is patterned by dry etching, and then subjected to a plasma treatment using oxygen or nitrogen. Therefore, chlorine or fluorine residue that is used in the dry etching is removed from the surface of the gate electrode 18.

Accordingly, even when the gate electrode 18 is heated, the oxidation of surface of the gate electrode 18 can be suppressed as compared with a case where chlorine or fluorine that is used in dry etching and remains in the surface of the gate electrode 18 is not removed and annealing is carried out in an atmospheric pressure environment.

After the annealing step, the interlayer film forming step is carried out. In this embodiment, the semiconductor layer 16 is annealed before the interlayer film forming step. Therefore, in the interlayer film forming step, the temperature applied to the substrate during formation of the first interlayer film 19 may be about 250° C.

### Fourth Embodiment

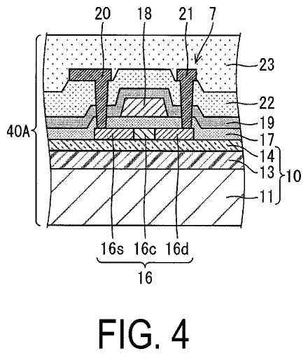

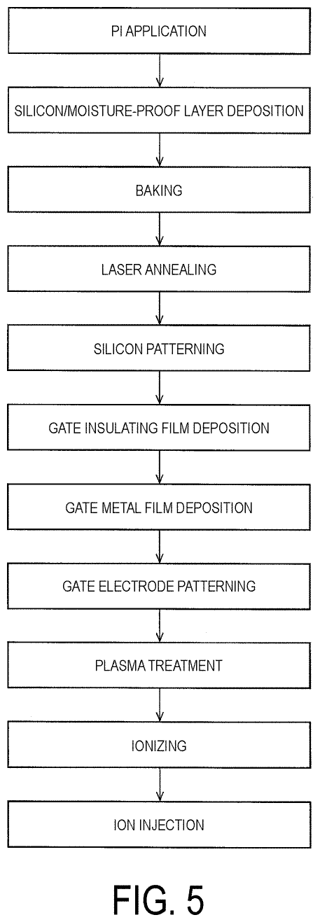

A fourth embodiment of the disclosure will be described below by using FIGS. 4 and 5. For easy description, components having the same functions as those of the components described in the first to third embodiments are appended with the same reference signs, and the description thereof is omitted.

FIG. 4 is a cross-sectional view illustrating a configuration of the TFT substrate 40A according to the second embodiment of the disclosure. FIG. 5 is a chart illustrating a process of manufacturing the TFT substrate 40A according to the second embodiment of the disclosure. The organic EL display device 1 illustrated in FIG. 1 may have the TFT substrate 40A instead of the TFT substrate 40.

The TFT substrate 40A is manufactured in the same manner as in the method for manufacturing the TFT substrate 40 except for after the plasma treatment step.

As illustrated in FIGS. 4 and 5, immediately after the gate electrode 18 is patterned by dry etching, the substrate, in which the gate electrode 18 is exposed, is subjected to a plasma treatment using oxygen (O₂) or nitrogen (N₂) in the plasma treatment step, and then subjected to an ionizing treatment using an ionizer in irradiation.

By this ionizing treatment, static electricity that remains in the gate electrode 18 and the gate wiring line G by the plasma treatment can be removed. Thus, an effect of injecting ions into the semiconductor layer 16 can be enhanced in the next step.

After the ionizing treatment, impurity ions such as boron ions are injected into the semiconductor layer 16 by using the gate electrode 18 as a mask, as illustrated in FIG. 3D (ion injection step). As a result, the source region 16s and the drain region 16d between which the channel region 16c is interposed are formed in the semiconductor layer 16. Furthermore, the ionizing treatment is carried out before the ion injection step, and thus ions can be effectively injected into the semiconductor layer 16.

Subsequently, the TFT substrate 40A is completed by the same method as the method for manufacturing the TFT substrate 40.

### Experimental Results Regarding Needle-Shaped and Granular Crystals

FIGS. 6A to 8B illustrate states of cross sections of gate electrodes and results of quantitative analysis. A quantitative analysis was carried out by changing the annealing condition.

FIGS. 6A and 6B are views illustrating a state of the gate electrode that was removed from a furnace immediately after annealing a substrate having the gate electrode, thus abruptly bringing back the temperature to the atmospheric temperature (quenching). FIG. 6A illustrates a cross section of the gate electrode when the substrate having the gate electrode was removed from the furnace immediately after annealing. FIG. 6B is a result of quantitative analysis of the gate electrode of FIG. 6A.

FIGS. 7A and 7B are views illustrating a state of the gate electrode, when the substrate having the gate electrode was removed from a furnace, after annealing and allowing the temperature in the furnace to decrease down to 50° C. FIG. 7A illustrates a cross section of the gate electrode when the substrate having the gate electrode was annealed, then the temperature in the furnace is allowed to decrease down to 50° C. and then the substrate was removed from the furnace. FIG. 7B is a result of quantitative analysis of the gate electrode of FIG. 7A.

FIGS. 8A and 8B are views illustrating a state of the gate electrode, when the substrate having the gate electrode was removed from a furnace after annealing in a low-oxygen environment.

FIG. 8A illustrates a cross section of the gate electrode when the substrate having the gate electrode was annealed in a low-oxygen environment and then removed from the furnace. FIG. 8B is a result of quantitative analysis of the gate electrode of FIG. 8A.

For the gate electrodes illustrated in FIGS. 6A to 8B, pure molybdenum was used. In annealing, the gate electrode was heated at 450° C.

When the gate electrode was quenched by removing the substrate from the furnace immediately after annealing, a needle-shaped crystal was formed on the surface of the gate electrode as illustrated in FIG. 6A. At a location named “measured location” illustrated in FIG. 6A, a quantitative analysis of elements was carried out. As seen from FIG. 6B, a large amount of carbon was detected and molybdenum on the surface of the gate electrode was found to be oxidized.

After annealing, the temperature in the furnace was allowed to decrease down to 50° C., and the substrate was removed from the furnace. In such a case, a granular crystal was formed on the surface of the gate electrode as illustrated in FIG. 7A. At a location named “measured location” illustrated in FIG. 7A, a quantitative analysis of elements was carried out. As seen from FIG. 7B, a large amount of carbon was detected and molybdenum on the surface of the gate electrode was found to be oxidized.

The substrate was annealed in the furnace under reduced pressure in a low-oxygen environment and removed from the furnace. In such a case, neither needle-shaped nor granular crystal was formed on the surface of the gate electrode as illustrated in FIG. 8A. At a location named “measured location” illustrated in FIG. 8A, a quantitative analysis of elements was carried out. As seen from FIG. 8B, the amount of molybdenum in the surface was greater than the amount of oxygen or the amount of carbon. Thus, the oxidation on the surface of the gate electrode was found to be prevented.

On the cross section of a gate electrode that was not annealed, neither needle-shaped nor granular crystal was formed, similar to FIG. 8A. In the gate electrode that was not annealed, the amount of molybdenum in the surface was greater than the amount of oxygen or the amount of carbon and the surface of the gate electrode was not oxidized in the same way as the result of quantitative analysis illustrated in FIG. 8B.

This shows that the needle-shaped and granular crystals formed on the surface of the gate electrode are formed by quenching molybdenum, which is oxidized by heat.

### Supplement

A method for manufacturing an active matrix substrate (TFT substrate 40) according to a first aspect of the disclosure is a method for manufacturing an active matrix substrate (TFT substrate 40) having the TFT 7 with a top gate structure on the substrate 10 including: (i) forming a gate insulating film 17 on the substrate 10, the gate insulating film 17 covering the semiconductor layer 16 formed in an island shape; (ii) forming a metal film on the gate insulating film 17 followed by dry etching to form the gate electrode 18, the metal film forming the gate electrode 18 of the TFT 7 on the gate insulating film 17; and (iii) subjecting the gate electrode 18 to a plasma treatment using oxygen or nitrogen, after step (ii), the gate electrode 18 being exposed.

According to the configuration, the gate electrode is patterned by dry etching. Therefore, the gate electrode can have a tapered shape. Thus, the coverage of the gate electrode and the first interlayer film covering the gate electrode can be improved. According to the configuration, the gate electrode is formed, and the exposed gate electrode is then subjected to a plasma treatment using oxygen or nitrogen. Therefore, chlorine or fluorine element that is used during the patterning by dry etching and attached to the gate electrode can be removed. Accordingly, the oxidation of surface of the gate electrode due to heat applied to the substrate for activation of the semiconductor layer can be prevented.

It is preferable that a method for manufacturing an active matrix substrate (TFT substrate 40) according to a second aspect of the disclosure include, (iv) injecting impurity ions into the semiconductor layer 16 by using the gate electrode 18 as a mask after step (iii), and (v) forming an interlayer film containing silicon oxide or silicon nitride on the gate insulating film 17 under heating the substrate at from 300° C. to 430° C., the interlayer film covering the gate electrode 18, after step (iv) (interlayer film forming step).

According to the configuration, the semiconductor layer is annealed by heating, resulting in activation. In step (v) (the interlayer film forming step), the first interlayer film is in the process of accumulation on the gate electrode that is exposed before step (v). Therefore, the surface of the gate electrode is not exposed. Accordingly, even when the substrate is heated, the oxidation of surface of the gate electrode can be prevented. That is, in step (v) (the interlayer film forming step), the semiconductor layer can be annealed while the interlayer film is formed.

According to the configuration, when the substrate is heated at not lower than 300° C., the semiconductor layer can be sufficiently annealed, resulting in activation. When the substrate is heated at not higher than 430° C., the deterioration of the first interlayer film 19 that is formed can be prevented.

In a method for manufacturing an active matrix substrate (TFT substrate 40) according to a third aspect of the disclosure, the gate electrode 18 may include molybdenum or a molybdenum alloy. Thus, a gate electrode having a small resistance value can be formed.

It is preferable that a method for manufacturing an active matrix substrate (TFT substrate 40) according to a fourth aspect of the disclosure include

(vi) applying a polyimide to the support 11 to form a polyimide film (plastic film 13), and (vii) forming an inorganic insulating film (moisture-proof layer 14) on the polyimide film (plastic film 13) to form the substrate 10.

It is preferable that a method for manufacturing an active matrix substrate (TFT substrate 40A) according to a fifth aspect of the disclosure include,

(viii) subjecting the gate electrode 18 to an ionizing treatment before step (iv). According to the configuration, the effect of injecting ions into the semiconductor layer can be enhanced in a subsequent step.

In a method for manufacturing an active matrix substrate (TFT substrate 40) according to a sixth aspect of the disclosure, the mass concentration of molybdenum or molybdenum alloy in the surface of the gate electrode in the third aspect may be greater than that of oxygen.

In a method for manufacturing an active matrix substrate (TFT substrate 40) according to a seventh aspect of the disclosure, the mass concentration of molybdenum or molybdenum alloy in the surface of the gate electrode in the third aspect may be greater than that of carbon.

In a method for manufacturing an active matrix substrate (TFT substrate 40) according to an eighth aspect of the disclosure, the semiconductor layer 16 may include a low-temperature polysilicon.

A method for manufacturing an organic EL display device according to a ninth aspect of the disclosure may include forming the organic EL layer 26 and the sealing layer 42 sealing the organic EL layer 26 on the active matrix substrate (TFT substrate 40) manufactured by the method for manufacturing an active matrix substrate (TFT substrate 40) according to the first to seventh aspects.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

1 Organic EL display device
2 Organic EL substrate
5 Display region
6 Frame region
7 TFT
10 Substrate
16 Semiconductor layer
16c Channel region
16s Source region
16d Drain region
17 Gate insulating film
18 Gate electrode
19 First interlayer film (interlayer film)
20 Source electrode
21 Drain electrode
22 Second interlayer film
23 Interlayer insulating film
24 Lower electrode
25 Edge cover
26 Organic EL layer
27 Upper electrode
28, 30 Inorganic layer
29 Organic layer
35 Frame bank
40 TFT substrate (active matrix substrate)
41 Organic EL element
42 Sealing layer

1. (canceled)

2. A method for manufacturing an active matrix substrate including a Thin Film Transistor (TFT) with a top gate structure on a substrate comprising:
(i) forming a gate insulating film on the substrate, the gate insulating film covering a semiconductor layer formed in an island shape on the substrate;
(ii) forming a metal film on the gate insulating film followed by dry etching to form a gate electrode, the metal film forming the gate electrode of the TFT;
(iii) subjecting the gate electrode to a plasma treatment using oxygen or nitrogen after step (ii), the gate electrode being exposed;
(iv) injecting an impurity ion into the semiconductor layer by using the gate electrode as a mask after step (iii); and
(v) forming an interlayer film including silicon oxide or silicon nitride on the gate insulating film under heating the substrate at from 300° C. to 430° C. after step (iv), the interlayer film covering the gate electrode.

3. The method for manufacturing an active matrix substrate according to claim 2,
wherein the gate electrode includes molybdenum or a molybdenum alloy.

4. The method for manufacturing an active matrix substrate according to claim 2, further comprising:
(vi) applying a polyimide to a support to form a polyimide film; and
(vii) forming an inorganic insulating film on the polyimide film to form the substrate.

5. The method for manufacturing an active matrix substrate according to claim 2, further comprising:
(viii) subjecting the gate electrode to an ionizing treatment, after step (iii), and before step (iv).

6. The method for manufacturing an active matrix substrate according to claim 3,
wherein the molybdenum or the molybdenum alloy in a surface of the gate electrode has a mass concentration greater than a mass concentration of oxygen.

7. The method for manufacturing an active matrix substrate according to claim 3,
wherein the molybdenum or the molybdenum alloy in a surface of the gate electrode has a mass concentration greater than a mass concentration of carbon.

8. The method for manufacturing an active matrix substrate according to claim 2,
wherein the semiconductor layer includes a low-temperature polysilicon.

9. A method for manufacturing an organic EL display device comprising:
forming an organic EL layer and a sealing layer on an active matrix substrate manufactured by the method for manufacturing an active matrix substrate according to claim 2, the sealing layer sealing the organic EL layer.
